(19) United States
(12) Patent Application Publication
(10) Pub. No.: US 2022/0187349 A1
(43) Pub. Date: Jun. 16, 2022

(54) MISSING DATA CORRECTION METHOD AND APPARATUS

(71) Applicant: Electronics and Telecommunications Research Institute, Daejeon (KR)

(72) Inventors: Sewan HEO, Daejeon (KR); Tai-yeon KU, Daejeon (KR); Wan Ki PARK, Daejeon (KR)

(73) Assignee: Electronics and Telecommunications Research Institute, Daejeon (KR)

(21) Appl. No.: 17/486,236

(22) Filed: Sep. 27, 2021

(30) Foreign Application Priority Data
Dec. 10, 2020 (KR) 10-2020-0172621

(51) Int. Cl. G01R 22/06; G01R 22/10

(52) U.S. Cl. CPC G01R 22/068; G01R 22/10; G01R 22/063

(57) ABSTRACT

Provided is a missing data correction method and apparatus, and more particularly, a missing data correction method that estimates missing power and energy from an electricity meter in consideration of a case in which power data and energy data collected from the electricity meter are missing and generates continuous power data according to the estimated power and energy.

### CROSS-REFERENCE TO RELATED APPLICATION

This application claims the benefit of Korean Patent Application No. 10-2020-0172621 filed on Dec. 10, 2020, in the Korean Intellectual Property Office, the entire disclosure of which is incorporated herein by reference for all purposes.

### BACKGROUND

### 1. Field of the Invention

One or more example embodiments relate to a missing data correction method and apparatus, and more particularly, to a method and apparatus for estimating and correcting missing data in a process of collecting power data from an electricity meter.

### 2. Description of the Related Art

An electricity meter refers to an instruction that integrates, measures, and records active power of connected circuits over time and measures an amount of electricity used over time. An amount of electricity used is divided into power and an energy. The power refers to an amount of energy used per unit time and represents an instantaneous intensity of electricity used. Here, the power is classified into active power that is actually used, reactive power that is not used, and apparent power that is a sum of the active power and the reactive power. The energy represents an amount of energy used by accumulating power.

Also, the electricity meter stores data for a certain period of time by itself, but does not store data for a long period of time. Therefore, to analyze power data or energy data, data needs to be periodically stored in a separate data storage.

However, if a communication state is temporarily poor, data may be missing, that is, omitted without being saved. In this case, reliability of data may not be guaranteed due to an error of an operator.

Accordingly, to overcome the aforementioned issues, there is a need for a method of estimating and correcting data that is not stored or missing due to an error of an electricity meter.

### SUMMARY

Example embodiments provide an apparatus and method that may generate continuous power data by estimating and correcting missing data in currently collected power data using previously collected power data when power data collected from an electricity meter is partially missing and discontinuous accordingly.

According to an aspect, there is provided a missing data correction method including collecting discontinuous power data and energy data from an electricity meter and determining missing sections of power data according to a power use; estimating missing power data in a collecting process corresponding to each of the missing sections; accumulating power data estimated in each of the missing sections over time, estimating energy data for each missing section, and calculating a total accumulation size; comparing an energy before and an energy after a corresponding missing section from the collected energy data and calculating a missing size of energy; comparing an accumulation size of the estimated energy data and a missing size of the collected energy data and determining a correction ratio corresponding to each of the missing sections; and correcting the estimated power data and energy data by applying the determined correction ratio to each of the missing sections.

The determining of the missing sections of the power data may include determining discontinuous missing sections of a time unit in the collecting process of the electricity meter according to a flow of power.

The estimating of the missing power data may include extracting a plurality of power data generated in the same time zone as a time zone of the missing section in consideration of a collection section of power data collected from the electricity meter; and estimating the missing power data from the plurality of power data.

The estimating of the missing power data may include calculating an accumulation size of a total energy accumulated in a missing section from the estimated energy data.

The determining of the correction ratio may include determining a difference in an energy between a starting point and an ending point of each of the missing sections from the energy data; and calculating a correction ratio corresponding to each of the missing sections according to the determined difference in the energy of each of the missing sections.

The calculating of the correction ratio may include calculating the correction ratio corresponding to each of the missing sections by dividing a missing size of energy data according to the difference in the energy by the accumulation size of the estimated energy data.

The correcting of the estimated power data and energy data may include correcting the estimated power data by applying the correction ratio estimated in each of the missing sections to adjust a size of the power data.

The correcting of the estimated power data and energy data may include 1) adjusting a size of the estimated power and energy to decrease if the correction ratio is less than ‘1,’ 2) adjusting the size of the estimated power and energy to increase if the correction ratio is greater than ‘1,’ and 3) maintaining the size of the estimated power and energy if the correction ratio is equal to ‘1.’

The correcting of the estimated power data and energy data may include the correcting energy data for each missing section by accumulating the corrected power data.

The missing data correction method may further include generating continuous power data by substituting the corrected power data and energy data into a missing section of power data. According to another aspect, there is provided a missing data correction apparatus including a processor. The processor is configured to collect discontinuous power data and energy data from an electricity meter and determine missing sections of power data according to a power use, estimate missing power data in a collecting process corresponding to each of the missing sections, accumulate power data estimated in each of the missing sections over time, estimate energy data for each missing section, and calculate a total accumulation size, compare an energy before and an energy after a corresponding missing section from the collected energy data and calculate a missing size of energy, compare an accumulation size of the estimated energy data and a missing size of the collected energy data and determine a correction ratio corresponding to each of the missing sections, correct the estimated power data and energy data by applying the determined correction ratio to each of the missing sections, and generate continuous power data and energy data by substituting the corrected power data and energy data into a missing section of power data.

The processor may be configured to determine discontinuous missing sections of a time unit in the collecting process of the electricity meter according to a flow of power.

The processor may be configured to extract a plurality of power data generated in the same time zone as a time zone of the missing section in consideration of a collection section of power data collected from the electricity meter, and estimate the missing power data from the plurality of power data.

The processor may be configured to calculate an accumulation size of a total energy accumulated in a missing section from the estimated energy data.

The processor may be configured to determine a difference in an energy between a starting point and an ending point of each of the missing sections from the energy data, and calculate a correction ratio corresponding to each of the missing sections according to the determined difference in the energy of each of the missing sections.

The processor may be configured to calculate the correction ratio corresponding to each of the missing sections by dividing a missing size of energy data according to the difference in the energy by the accumulation size of the estimated energy data.

The processor may be configured to correct the estimated power data by applying the correction ratio estimated in each of the missing sections to adjust a size of the power data.

The processor may be configured to 1) adjust a size of the estimated power and energy to decrease if the correction ratio is less than ‘1,’ 2) adjust the size of the estimated power and energy to increase if the correction ratio is greater than ‘1,’ and 3) maintain the size of the estimated power and energy if the correction ratio is equal to ‘1.’

The processor may be configured to correct the energy data for each missing section by accumulating the corrected power data.

Additional aspects of example embodiments will be set forth in part in the description which follows and, in part, will be apparent from the description, or may be learned by practice of the disclosure.

According to example embodiments, a missing data correction method and apparatus may secure continuous power data by estimating power and an energy for each missing section using previously collected power data although power data collected from an electricity meter is partially missing.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 illustrates an example of describing a series of processes of processing missing data in power data collected from an electricity meter according to an example embodiment;

FIGS. 2A and 2B are graphs showing an example of determining a missing section from power data according to an example embodiment;

FIGS. 3A and 3B are graphs showing an example of determining a process of estimating power data of a missing section based on the graphs of FIGS. 2A and 2B according to an example embodiment;

FIGS. 4A and 4B are graphs showing an example of generating continuous power data by correcting and estimating power data and energy data according to an example embodiment; and

FIG. 5 is a flowchart illustrating an example of a missing data correction method according to an example embodiment.

### DETAILED DESCRIPTION

Hereinafter, example embodiments will be described in detail with reference to the accompanying drawings.

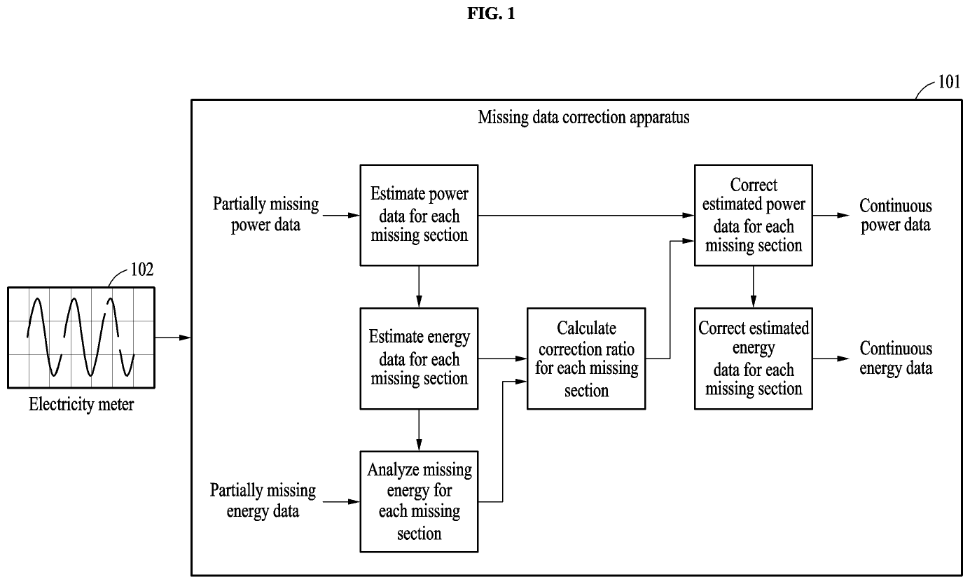

FIG. 1 illustrates an example of describing a series of processes of processing missing data in power data collected from an electricity meter according to an example embodiment.

In general, a missing data correction apparatus collects power data and energy data from an electricity meter. Here, if a communication error occurs between the electricity meter and the missing data correction apparatus, the missing data correction apparatus does not store and collect all of power data and energy data in the same time zone, which may lead to causing data missing. Such data missing may occur not in a specific time zone but in a plurality of time zones. Herein, proposed is a method capable of independently processing such missing data in each of missing sections occurring in the plurality of time zones.

Referring to FIG. 1, a missing data correction apparatus 101 may process missing data included in power data collected from an electricity meter 102. Here, the missing data correction apparatus 101 may collect partially missing discontinuous power data and energy data. Here, the power data and the energy data may be used for analysis or simulation of electricity usage pattern. However, in this case, since continuous data is required, discontinuous data may be generated as continuous data herein. Through a series of processes described below, continuous power data and energy data may be generated.

The missing data correction apparatus 101 may collect discontinuous power data from the electricity meter 102. The missing data correction apparatus 101 may identify a section in which the collected power data is not continuous at a predetermined (alternatively, desired) time unit as a section with missing and, based thereon, may determine missing sections according to a power use. Here, the determined missing sections may be formed at different intervals in different time zones. Also, a section in which missing is continuous based on a time unit may be determined as a single missing section.

For example, with the assumption that a section with continuous missing is present in each of ‘11:00˜11:20,’ ‘13:11˜14:32,’ and ‘21:02˜21:13’ in power data collected for 24 hours a day, the missing data correction apparatus 101 may determine each section with continuous missing as a single missing section and may determine that a total of three missing sections are present. The missing data correction apparatus 101 may estimate missing power data in each missing section. In collecting power data, the missing data correction apparatus 101 may estimate missing power data in a corresponding missing section by averaging power data generated in the same time zone on different days in the power data collected from the electricity meter 102. That is, the missing data correction apparatus 101 may estimate, as the missing power data, power that may be predicted to have been collected in the corresponding missing section from the power data generated in the same time zone on different days.

The missing data correction apparatus 101 may generate energy data in each missing section by accumulating the estimated power data over time. The missing data correction apparatus 101 may calculate energy data by accumulating power data of each missing section over time, starting with an energy of energy data just before a corresponding missing section occurs.

For example, if an energy of energy data just before a missing section occurs is 10 kWh and power of power data for 5 minutes corresponding to the missing section is 12 kW, an energy added after 5 minutes is 1 kWh and an energy value of subsequent energy data may be 11 kWh.

The missing data correction apparatus 101 may calculate a total accumulation size accumulated in the missing section for the estimated power data.

The missing data correction apparatus 101 may estimate missing energy data for each missing section based on the energy data. The missing data correction apparatus 101 may calculate a missing size of energy for a corresponding missing section by calculating a difference between a value of energy data before missing and energy data after missing. Here, the missing size of energy may be determined as an amount of power by the difference between the values. Here, “before missing” may represent a section without missing before a corresponding missing section starts and “after missing” may represent a section with no more missing power data after the missing section ends. Since there is continuous data before missing and after missing, there is a starting point value of missing just before missing and there is an ending point value of missing immediately after missing.

For example, if energy data before missing occurs is 10 kWh and energy data after missing occurs is 15 kWh, the missing data correction apparatus 101 may determine, as a missing size of energy, 5 kWh that is a difference value between the energy data before the missing occurs and the energy data after the missing occurs.

The missing data correction apparatus 101 may compare an accumulation size of the estimated energy data and a missing size of the collected energy data and may determine a correction ratio corresponding to each of the missing sections. In detail, the missing data correction apparatus 101 may calculate the correction ratio corresponding to each of the missing sections by dividing the missing size of the collected energy data by the accumulation size of the estimated energy data. For example, if a missing size of energy data collected in a missing section is 12 kWh and an accumulation size of estimated energy data is 10 kWh, the missing data correction apparatus 101 may calculate, as a correction ratio of the corresponding missing section, 1.2 times that is obtained by dividing the missing size of the collected energy data by the accumulation size of the estimated energy data. The correction ratio may be used to correct the estimated power and energy.

The missing data correction apparatus 101 may adjust a size of estimated power by multiplying power of power data accumulated for each missing section by a correction ratio corresponding to a corresponding missing section. Here, the missing data correction apparatus 101 may adjust the estimated power to further decrease if the correction ratio is less than 1, may adjust the estimated power to further increase if the correction ratio is greater than 1, and may maintain the size of the estimated power if the correction ratio is equal to 1.

The missing data correction apparatus 101 may integrate power data corrected by applying the correction ratio for each missing section with power data collected from the electricity meter 102. Here, although data of a missing section is absent in the power data collected from the electricity meter 102 at a point in time of collection, the data may be integrated with the corrected power data through the aforementioned process and may be corrected as continuous power data. Then, the missing data correction apparatus 101 may generate continuous energy data by accumulating the power data in which the size of power is corrected.

The missing data correction apparatus 101 may integrate the corrected energy data generated for each missing section into the input energy data. Although data of a missing section is absent in the energy data collected from the electricity meter 102 at a point in time of collection, continuous energy data may be generated as the corrected energy data is combined.

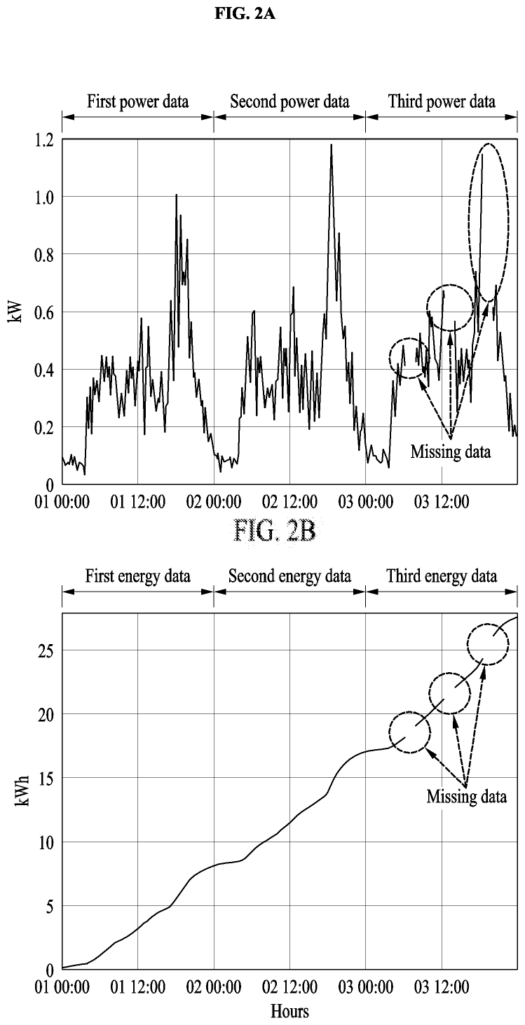

FIGS. 2A and 2B are graphs showing an example of determining a missing section from power data according to an example embodiment.

Referring to FIGS. 2A and 2B, a missing data correction apparatus according to an example embodiment may determine power data and a missing section of energy data from power data and energy data collected for a predetermined collection section.

Referring to FIG. 2A, power data and energy data were collected for 3 days and power data corresponding to a first day, power data corresponding to a second day, and power data corresponding to a third day may be defined as first power data, second power data, and third power data, respectively. Energy data corresponding to the first day, energy data corresponding to the second day, and energy data corresponding to the third day may be defined as first energy data, second energy data, and third energy data, respectively. Each piece of power data and energy data may be data collected for 24 hours from 0 o'clock to 0 o'clock a next day.

Referring to FIG. 2B, the first energy data, the second energy data, and the third energy data may be independent of each other and vary over time, however, may represent repetitive similar patterns. Also, in the first energy data, the second energy data, and the third energy data, as power data corresponding to each day is accumulated and calculated, a start value of a present day matches an end value of a previous day. Also, an end value of the present day may be a start value of a next day.

Referring to the graph, there is no missing power data corresponding to the first day and the second day. Three missing sections are present in the third power data and the third energy data corresponding to the third day. Here, missing sections in which power data and energy data are simultaneously missing are present in the same time zone.

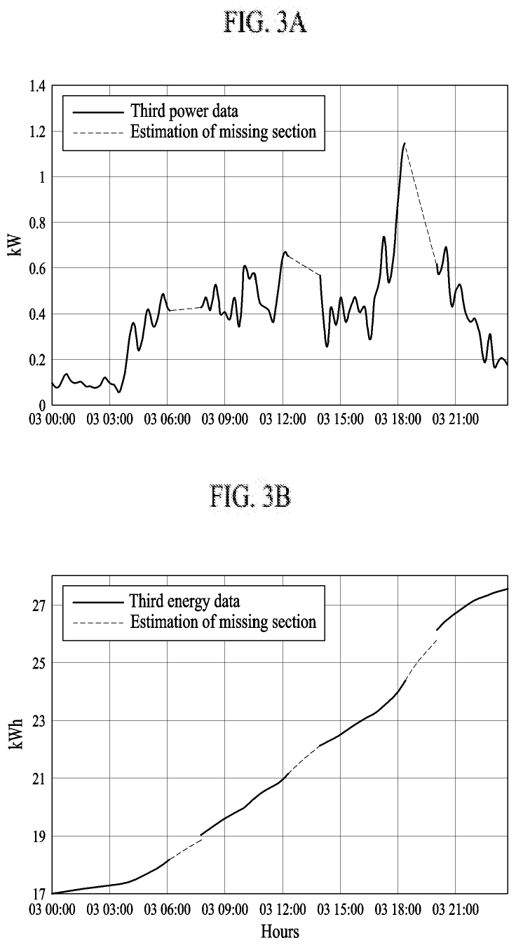

FIGS. 3A and 3B are graphs showing an example of determining a process of estimating power data of a missing section based on the graphs of FIGS. 2A and 2B according to an example embodiment.

Referring to the graph shown in FIG. 3A, power data and energy data were simultaneously missing in three missing sections. Power data and energy data in a missing section may be estimated by an interpolation method. The interpolation method is a method of estimating a value of the missing section based on an assumption that power constantly varies between a starting point and an end point of the missing section. However, an accuracy of the interpolation method may be low when the period of time of the missing section is long, while an accuracy may be high when a period of the missing section is short.

The graph shown in FIG. 3B shows a result of estimating energy data through accumulation of estimated power by the interpolation method to the missing section. However, the estimated energy data differs from an actually measured value. Therefore, an end value of energy data in which power is accumulated may not be continuous with actually collected data.

Here, the example embodiment disclosed herein may provide a method of estimating and correcting power data in the missing section. According to the provided method, the example embodiment may collect discontinuous power data and energy data from an electricity meter and may determine missing sections of power data according to a power use. Also, the example embodiment may guarantee reliability of power data and energy data collected from a power grid by determining a correction ratio according to the power data and the energy data and by generating continuous power data and energy data according to the correction ratio.

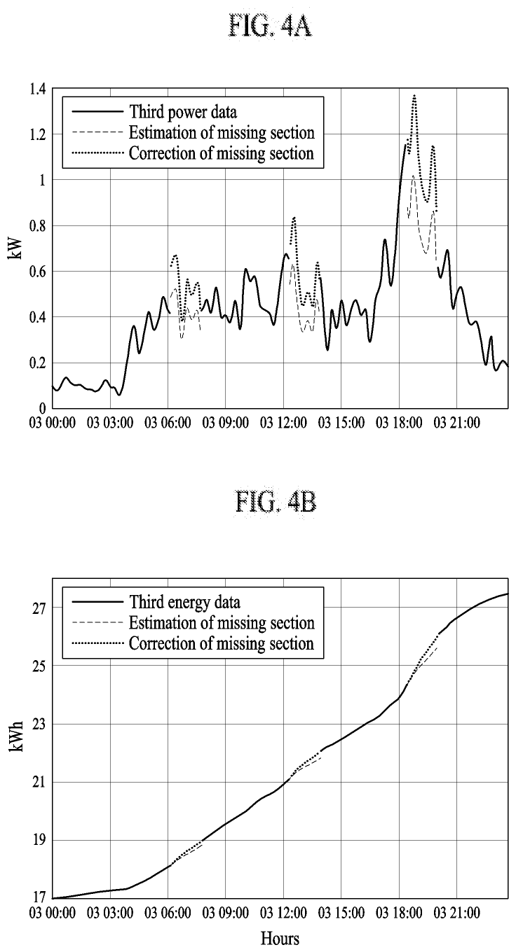

FIGS. 4A and 4B are graphs showing an example of generating continuous power data by correcting and estimating power data and energy data according to an example embodiment.

A missing data correction apparatus according to an example embodiment may estimate missing power data in the missing sections of the third power data and the third energy data shown in the graph of FIGS. 2A and 2B through data estimation and correction.

Referring to FIGS. 4A and 4B, the three missing sections according to the graph of FIGS. 2A and 2B are present in different time zones and power data of a corresponding missing section may be estimated in power data by averaging data of the same time zone in the first power data and the second power data.

The missing data correction apparatus may estimate energy data corresponding to each of the three missing sections appearing in the third energy data by accumulating the estimated power data. Here, the estimated energy data may not be continuous with subsequent actual collected data. To correct this, the missing data correction apparatus may calculate a correction ratio for each missing section.

The missing data correction apparatus may generate power data in which an amount of power is corrected and continuous by applying the calculated correction ratio to the power data collected from the power grid. The estimated data and the corrected data may differ from each other depending on a size of the correction ratio. In FIGS. 4A and 4B, since all of the correction ratios are greater than 1, the corrected power may be greater than the estimated power.

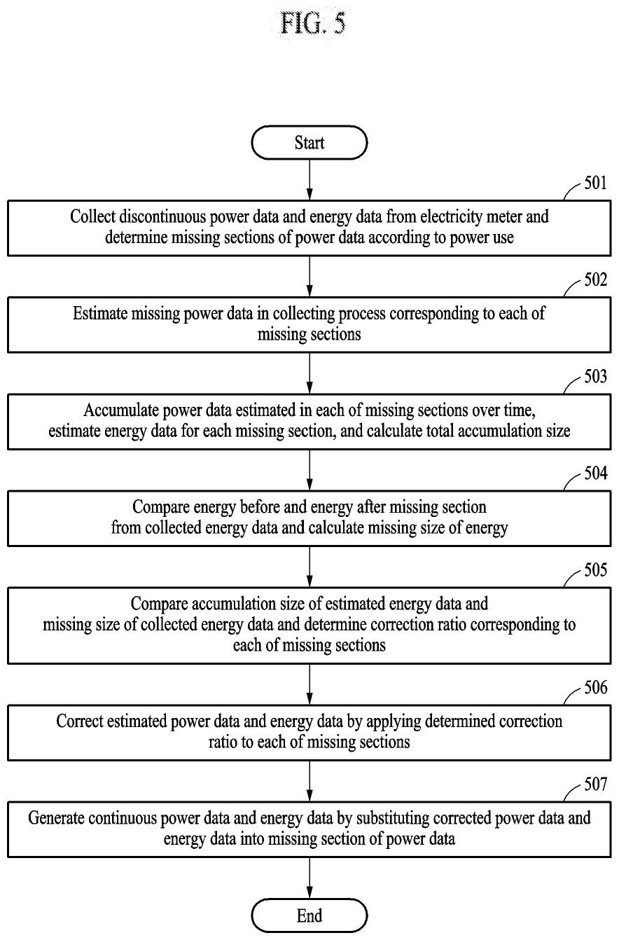

Also, the example embodiment may generate corrected energy data by accumulating corrected power data for each missing section. Since the correction ratio is applied to the corrected energy data, an end value of a corresponding missing section matches a subsequent actual collected value. FIG. 5 is a flowchart illustrating an example of describing a missing data correction method according to an example embodiment.

Referring to FIG. 5, in operation 501, a missing data correction apparatus according to an example embodiment may collect discontinuous power data and energy data from an electricity meter and determine missing sections of power data according to a power use. The missing data correction apparatus may determine discontinuous missing sections of a time unit in the collecting process of the electricity meter according to a flow of power.

In operation 502, the missing data correction apparatus may estimate missing power data in a collecting process corresponding to each of the missing sections. The missing data correction apparatus may extract a plurality of power data generated in the same time zone as a time zone of the missing section in consideration of a collection section of power data collected from the electricity meter. The missing data correction apparatus may estimate missing power data based on the plurality of power data.

That is, the plurality of power data may refer to past data that is previously collected through the electricity meter, and the missing data correction apparatus may extract power data generated in the same time zone as the time zone of the missing section from the past data of the electricity meter. For example, the missing data correction apparatus may estimate missing power data by averaging power data collected in the same time zone of other days according to a collection period of the power data. Here, the missing data correction apparatus may estimate missing power data of a time unit corresponding to each of the missing sections.

In operation 503, the missing data correction apparatus may accumulate power data estimated in each of the missing sections over time, estimate energy data for each missing section, and calculate a total accumulation size. The energy data may be a result of accumulating a sum of missing power in power data estimated in the respective missing sections and the accumulation size may be a total energy accumulated in the respective missing sections.

In operation 504, the missing data correction apparatus may compare an energy before and an energy after a corresponding missing section from the collected energy data and calculate a missing size of energy. The missing data correction apparatus may calculate a missing energy for each missing section by comparing energy data before the corresponding missing section and energy data after the missing section.

The energy data before the missing section may represent continuous energy data before the missing section starts. Conversely, the energy data after the missing section may represent continuous energy data after the missing section ends.

The missing data correction apparatus may estimate a missing energy in a corresponding missing section using a difference value in an energy as a result of comparing energy data before missing occurs and the energy data after missing occurs.

In operation 505, the missing data correction apparatus may compare an accumulation size of the estimated energy data and a missing size of the collected energy data and determine a correction ratio corresponding to each of the missing sections. The missing data correction apparatus may determine a difference in an energy between a starting point and an ending point of each of the missing sections from the energy data.

The missing data correction apparatus may calculate a correction ratio corresponding to each of the missing section according to the determined difference in the energy of each of the missing sections. Here, the missing data correction apparatus may calculate the correction ratio corresponding to each of the missing sections by dividing the missing size of energy data according to the difference in the energy by the accumulation size of the estimated energy data.

In operation 506, the missing data correction apparatus may correct the estimated power data and energy data by applying the determined correction ratio to each of the missing sections. The missing data correction apparatus may correct the estimated power data by applying the correction ratio estimated in each of the missing sections to adjust a size of the power data.

Here, the missing data correction apparatus may correct the estimated power data and energy data to 1) decrease a size of the estimated power and energy if the correction ratio is less than ‘1,’ or 2) increase the size of the estimated power and energy if the correction ratio is greater than ‘1.’ Also, the missing data correction apparatus may correct the estimated power data and energy data to 3) maintain the size of the estimated power and energy if the correction ratio is equal to ‘1.’

Also, the missing data correction apparatus may correct the energy data for each missing section by accumulating the corrected power data.

In operation 507, the missing data correction apparatus may generate continuous power data by substituting the corrected power data and energy data into a missing section of power data.

The components described in the example embodiments may be implemented by hardware components including, for example, at least one digital signal processor (DSP), a processor, a controller, an application-specific integrated circuit (ASIC), a programmable logic element, such as a field programmable gate array (FPGA), other electronic devices, or combinations thereof. At least some of the functions or the processes described in the example embodiments may be implemented by software, and the software may be recorded on a recording medium. The components, the functions, and the processes described in the example embodiments may be implemented by a combination of hardware and software.

The method according to example embodiments may be written in a computer-executable program and may be implemented as various recording media such as magnetic storage media, optical reading media, or digital storage media.

Various techniques described herein may be implemented in digital electronic circuitry, computer hardware, firmware, software, or combinations thereof. The techniques may be implemented as a computer program product, i.e., a computer program tangibly embodied in an information carrier, e.g., in a machine-readable storage device (for example, a computer-readable medium) or in a propagated signal, for processing by, or to control an operation of, a data processing apparatus, e.g., a programmable processor, a computer, or multiple computers. A computer program, such as the computer program(s) described above, may be written in any form of a programming language, including compiled or interpreted languages, and may be deployed in any form, including as a stand-alone program or as a module, a component, a subroutine, or other units suitable for use in a computing environment. A computer program may be deployed to be processed on one computer or multiple computers at one site or distributed across multiple sites and interconnected by a communication network.

Processors suitable for processing of a computer program include, by way of example, both general and special purpose microprocessors, and any one or more processors of any kind of digital computer. Generally, a processor will receive instructions and data from a read-only memory or a random-access memory, or both. Elements of a computer may include at least one processor for executing instructions and one or more memory devices for storing instructions and data. Generally, a computer also may include, or be operatively coupled to receive data from or transfer data to, or both, one or more mass storage devices for storing data, e.g., magnetic, magneto-optical disks, or optical disks. Examples of information carriers suitable for embodying computer program instructions and data include semiconductor memory devices, e.g., magnetic media such as hard disks, floppy disks, and magnetic tape, optical media such as compact disk read only memory (CD-ROM) or digital video disks (DVDs), magneto-optical media such as floptical disks, read-only memory (ROM), random-access memory (RAM), flash memory, erasable programmable ROM (EPROM), or electrically erasable programmable ROM (EEPROM). The processor and the memory may be supplemented by, or incorporated in special purpose logic circuitry.

In addition, non-transitory computer-readable media may be any available media that may be accessed by a computer and may include both computer storage media and transmission media. Although the present specification includes details of a plurality of specific example embodiments, the details should not be construed as limiting any invention or a scope that can be claimed, but rather should be construed as being descriptions of features that may be peculiar to specific example embodiments of specific inventions. Specific features described in the present specification in the context of individual example embodiments may be combined and implemented in a single example embodiment. On the contrary, various features described in the context of a single embodiment may be implemented in a plurality of example embodiments individually or in any appropriate sub-combination. Furthermore, although features may operate in a specific combination and may be initially depicted as being claimed, one or more features of a claimed combination may be excluded from the combination in some cases, and the claimed combination may be changed into a sub-combination or a modification of the sub-combination. Likewise, although operations are depicted in a specific order in the drawings, it should not be understood that the operations must be performed in the depicted specific order or sequential order or all the shown operations must be performed in order to obtain a preferred result. In a specific case, multitasking and parallel processing may be advantageous. In addition, it should not be understood that the separation of various device components of the aforementioned example embodiments is required for all the example embodiments, and it should be understood that the aforementioned program components and apparatuses may be integrated into a single software product or packaged into multiple software products.

The example embodiments disclosed in the present specification and the drawings are intended merely to present specific examples in order to aid in understanding of the present disclosure, but are not intended to limit the scope of the present disclosure. It will be apparent to those skilled in the art that various modifications based on the technical spirit of the present disclosure, as well as the disclosed example embodiments, can be made.

What is claimed is:

1. A missing data correction method comprising:
collecting discontinuous power data and energy data from an electricity meter and determining missing sections of power data according to a power use;
estimating missing power data in a collecting process corresponding to each of the missing sections;
accumulating power data estimated in each of the missing sections over time, estimating energy data for each missing section, and calculating a total accumulation size;
comparing an energy before and an energy after a corresponding missing section from the collected energy data and calculating a missing size of energy;
comparing an accumulation size of the estimated energy data and a missing size of the collected energy data and determining a correction ratio corresponding to each of the missing sections; and
correcting the estimated power data and energy data by applying the determined correction ratio to each of the missing sections.

2. The missing data correction method of claim 1, wherein the determining of the missing sections of the power data comprises determining discontinuous missing sections of a time unit in the collecting process of the electricity meter according to a flow of power.

3. The missing data correction method of claim 1, wherein the estimating of the missing power data comprises:
extracting a plurality of power data generated in the same time zone as a time zone of the missing section in consideration of a collection section of power data collected from the electricity meter; and
estimating the missing power data from the plurality of power data.

4. The missing data correction method of claim 1, wherein the estimating of the missing power data comprises calculating an accumulation size of a total energy accumulated in a missing section from the estimated energy data.

5. The missing data correction method of claim 1, wherein the determining of the correction ratio comprises:
determining a difference in an energy between a starting point and an ending point of each of the missing sections from the energy data; and
calculating a correction ratio corresponding to each of the missing sections according to the determined difference in the energy of each of the missing sections.

6. The missing data correction method of claim 5, wherein the calculating of the correction ratio comprises calculating the correction ratio corresponding to each of the missing sections by dividing a missing size of energy data according to the difference in the energy by the accumulation size of the estimated energy data.

7. The missing data correction method of claim 1, wherein the correcting of the estimated power data and energy data comprises correcting the estimated power data by applying the correction ratio estimated in each of the missing sections to adjust a size of the power data.

8. The missing data correction method of claim 6, wherein the correcting of the estimated power data and energy data comprises 1) adjusting a size of the estimated power and energy to decrease if the correction ratio is less than ‘1,’ 2) adjusting the size of the estimated power and energy to increase if the correction ratio is greater than ‘1,’ and 3) maintaining the size of the estimated power and energy if the correction ratio is equal to ‘1.’

9. The missing data correction method of claim 7, wherein the correcting of the estimated power data and energy data comprises correcting the energy data for each missing section by accumulating the corrected power data.

10. The missing data correction method of claim 9, further comprising:
generating continuous power data by substituting the corrected power data and energy data into a missing section of power data.

11. A missing data correction apparatus comprising a processor,
wherein the processor is configured to
collect discontinuous power data and energy data from an electricity meter and determine missing sections of power data according to a power use,
estimate missing power data in a collecting process corresponding to each of the missing sections,
accumulate power data estimated in each of the missing sections over time, estimate energy data for each missing section, and calculate a total accumulation size,
compare an energy before and an energy after a corresponding missing section from the collected energy data and calculate a missing size of energy,
compare an accumulation size of the estimated energy data and a missing size of the collected energy data and determine a correction ratio corresponding to each of the missing sections,
correct the estimated power data and energy data by applying the determined correction ratio to each of the missing sections, and
generate continuous power data and energy data by substituting the corrected power data and energy data into a missing section of power data.

12. The missing data correction apparatus of claim 11, wherein the processor is configured to determine discontinuous missing sections of a time unit in the collecting process of the electricity meter according to a flow of power.

13. The missing data correction apparatus of claim 11, wherein the processor is configured to
extract a plurality of power data generated in the same time zone as a time zone of the missing section in consideration of a collection section of power data collected from the electricity meter, and
estimate the missing power data from the plurality of power data.

14. The missing data correction apparatus of claim 11, wherein the processor is configured to calculate an accumulation size of a total energy accumulated in a missing section from the estimated energy data.

15. The missing data correction apparatus of claim 11, wherein the processor is configured to
determine a difference in an energy between a starting point and an ending point of each of the missing sections from the energy data, and
calculate a correction ratio corresponding to each of the missing sections according to the determined difference in the energy of each of the missing sections.

16. The missing data correction apparatus of claim 15, wherein the processor is configured to calculate the correction ratio corresponding to each of the missing sections by dividing a missing size of energy data according to the difference in the energy by the accumulation size of the estimated energy data.

17. The missing data correction apparatus of claim 11, wherein the processor is configured to correct the estimated power data by applying the correction ratio estimated in each of the missing sections to adjust a size of the power data.

18. The missing data correction apparatus of claim 17, wherein the processor is configured to 1) adjust a size of the estimated power and energy to decrease if the correction ratio is less than ‘1,’ 2) adjust the size of the estimated power and energy to increase if the correction ratio is greater than ‘1,’ and 3) maintain the size of the estimated power and energy if the correction ratio is equal to ‘1.’

19. The missing data correction apparatus of claim 10, wherein the processor is configured to correct the energy data for each missing section by accumulating the corrected power data.
